(19) United States
(12) Patent Application Publication
(10) Pub. No.: US 2001/0045655 A1
(43) Pub. Date: Nov. 29, 2001

(54) SEMICONDUCTOR DEVICE AND MANUFACTURING METHOD THEREOF

(76) Inventor: YOSHIHISA MATSUBARA, TOKYO (JP)

Correspondence Address: HELFGOTT & KARAS PC, 60TH FLOOR, EMPIRE STATE BUILDING, NEW YORK, NY, 101180110

(21) Appl. No.: 09/452,926

(22) Filed: Dec. 2, 1999

(30) Foreign Application Priority Data
Apr. 12, 1998 (JP) 346031/1998

(51) Int. Cl. H01L 23/48

(52) U.S. Cl. 257/758

(57) ABSTRACT

In the present invention, there is disclosed a semiconductor device whose copper interconnect is formed multilevel in structure; wherein at least one interlayer film lying between layers of the copper interconnect has a layered structure in which an amorphous carbon film containing fluorine and a SiO₂ film are laid in this order from the side of the underlying copper interconnect; a layered structure in which a silicon nitride and then a silicon nitride oxide or a silicon carbide are laid in this order; or a structure comprising a single silicon carbide layer. Such interlayer films serve as anti-reflective coatings.

### BACKGROUND OF THE INVENTION

1. Field of the Invention

The present invention relates to a semiconductor device and a manufacturing method thereof and more particularly to a method of preventing the reflection from a lower-level copper interconnect in a semiconductor device having a copper multilevel interconnect.

2. Description of the Related Art

In recent years, attempts to achieve a higher speed and a higher integration in the LSI device has proceeded, and there have arisen demands that further miniaturization and more densely spaced arrangement should be attained not only in the transistor bur also in the interconnect.

As a metal interconnect material, mainly Al is utilized, hitherto, but this is known to lead to a problem of electromigration (EM); that is, a temperature rise due to an increase in current density of the interconnect and a heat generated by the whole device causes some metal atoms within an interconnect layer to move, which creates voids in some parts, from which those atoms move out and may thereby bring about the severance of the interconnect. Further, in some parts where metal atoms are accumulated, grains called hillocks are formed and, giving stress on an insulating layer lying over the interconnect, these may cause to produce cracks.

To solve such problems, the use of an alloy in which a very small amount of Si or Cu is mixed with Al is proposed, but even this will become insufficient if attempts to attain further miniaturization and more densely spaced arrangement advance, and, therefore, the use of the copper interconnect which has a still higher reliability is under consideration.

Among metal materials, copper has the second lowest resistivity to silver (1.7 to 1.8 μΩ-cm, as against 3.1 μΩ-cm for AlCu) as well as an excellent EM resistance. Consequently, amidst the advance in achieving a still more densely spaced arrangement, establishment of novel techniques making use of these copper characteristics is very much sought after.

For instance, techniques wherein copper is employed as an interconnect material are disclosed in an article titled “A High Performance 1.8 V 0.20 μm CMOS Technology with Copper Metallization” in IEDM '97, pp. 769-772, and an article titled “Full Copper Wiring in a Sub-0.25 μm CMOS ULSI Technology” in IEDM '97, pp. 773-776.

Copper is a relatively difficult material to form a pattern by etching. Especially, in the application to a semiconductor device of sub-0.25 μm order, copper must be formed by a damascene metallization technique (hereinafter abbreviated as “damascene technique”).

This is carried out, for example, as shown in FIG. 7. Firstly, a first interconnect trench 72 is formed on a first interlayer insulating film 71 (FIG. 7(a)), and then a barrier metal layer 73 and a copper 74 are deposited thereon, in succession, by the electroplating method, the CVD (Chemical Vapour Deposition) method or the like (FIG. 7(b)). Subsequently, polishing by the chemical mechanical polishing (CMP) method is applied thereto till the surface of the first interlayer insulating film 71 is exposed, and, with planarization of the copper surface, a first-level interconnect 75 is accomplished in the form of damascene (FIG. 7(c)). In order to form another copper interconnect above this, after a second interlayer insulating film 76 is grown, a second interconnect trench 78 as well as a via hole 77 for a contact with the first-level interconnect 75 are formed by means of photolithography (FIG. 7 (d)) and then, by damascening with copper in the similar manner, a second-level interconnect 79 is formed (FIG. 7(e)). Incidentally, in the latter example cited above, it is mentioned that the top-level copper interconnect is formed as a flip chip module when a test chip is formed.

Copper is a metal relatively easily oxidized. When another copper interconnect is laid over a lower-level copper interconnect as described above, if, for example, silicon oxide is utilized for the interlayer insulating film, in forming the silicon oxide film, which is normally carried out in an oxidizing atmosphere using silane, the underlying copper is also subjected to oxidation. As a result, on the copper surface which is oxidized at the same time as the silicon oxide film is formed, the peeling-off of the film may take place, leading to a problem that a prescribed interlayer insulating film cannot be necessarily formed. For the examples cited above, it is not reported what materials are exactly utilized for, but, there is given an example wherein an etching stopper layer (silicon nitride or the like is normally used for this) is formed and thereafter an oxide film is formed.

Further, when the interlayer insulating film is patterned by means of photolithography, as described above, the resist becomes overexposed owing to the reflection from the underlying interconnect, and there arises a problem that a prescribed pattern cannot be formed. The afore-mentioned silicon nitride film that is normally used as an etching stopper layer has no anti-reflective effect. The problem becomes more acute as the miniaturization of the interconnect pattern proceeds and an appropriate counter measure is called for.

To prevent the reflection from the ordinary metal interconnect, the use of a SiON film is a well-known means. At this, the formation of a SiON film is generally carried out at a substrate temperature of 300 to 400° C. or so, adding a nitrogen oxide gas or a mixed gas of nitrogen and oxygen into a silane gas. However, if it is over the copper interconnect that the formation of a SiON film under such conditions is performed, the copper surface is oxidized as in the case of the SiO₂ film formation described above and, thus, a problem that a prescribed anti-reflective coating (ARC) cannot be formed is brought about.

### SUMMARY OF THE INVENTION

The present invention provides a semiconductor device that can overcome the problems described above.

In light of the above problems, the present invention relates to a semiconductor device whose copper interconnect is formed multilevel in structure; wherein at least one interlayer film lying between layers of the copper interconnect has a layered structure in which an amorphous carbon film containing fluorine (abbreviated as an a-C:F film, hereinafter) and a SiO₂ film are laid in this order from the side of the underlying copper interconnect.

Further, the present invention relates to a semiconductor device whose copper interconnect is formed multilevel in structure; wherein at least one interlayer film lying between layers of the copper interconnect has a layered structure in which a silicon nitride and a silicon nitride oxide are laid in this order from the side of the underlying copper interconnect; a layered structure in which a silicon nitride and a silicon carbide are laid in this order; or a single-layered structure of a silicon carbide layer.

In the present invention, when a trench or a via hole to form a copper interconnect by a damascene technique is formed over another copper interconnect, the film formation on the surface of the underlying copper interconnect is carried out under the condition that no oxygen is used, and even when the film formation that uses oxygen is performed subsequently, the copper surface remains unoxidized, and moreover the film being formed thereby has an antireflective effect so that the further miniaturization of the interconnect pattern can be readily coped with.

### BRIEF DESCRIPTION OF THE DRAWINGS

FIG. 1(a) to FIG. 1(d) are a series of schematic cross-sectional views illustrating the steps of a manufacturing method that is an embodiment of the present invention.

FIG. 2 is a schematic cross-sectional view showing a multilevel interconnect structure that is an embodiment of the present invention.

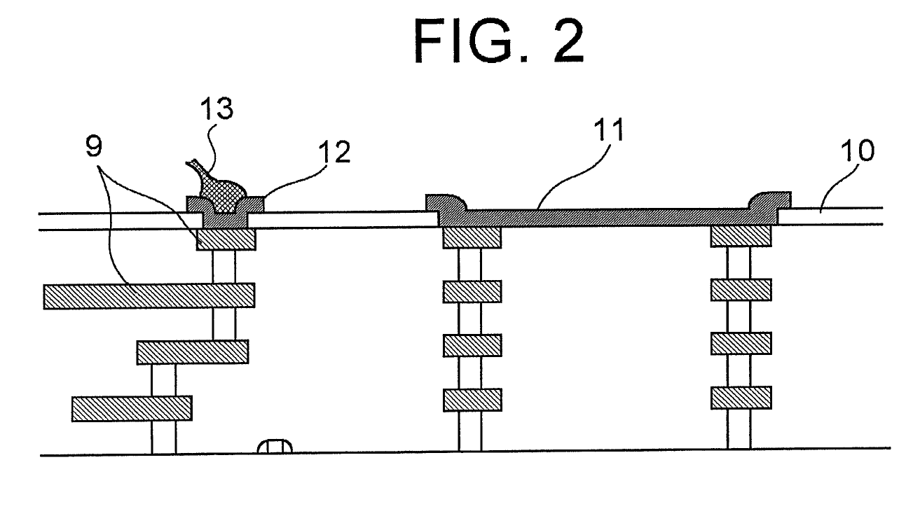

FIG. 3 is a graph showing the relationship between the thickness of copper oxide film on the copper surface and the substrate temperature.

FIG. 4 is a group of SIMS (Secondary Ion Mass Spectroscopy) charts showing the component distribution of the copper film surface when an a-C:F film is formed on the surface of the copper film and thereon a SiO₂ film is formed (b) at 400° C., and (c) at 450° C. FIG. 4(a) represents the state before the annealing.

FIG. 5 is a group of graphs showing the relationship between the reflectance and the wavelength in the cases that, on the surface of the copper, (a) an a-C:F film is formed, (b) a SiN film is formed, and (c) no other film is formed.

FIG. 6 is a schematic cross-sectional view showing a multilevel interconnect structure that is another embodiment of the present invention.

FIG. 7(a) to FIG. 7(e) are a series of schematic cross-sectional views illustrating the steps of a conventional manufacturing method of a multilevel interconnect structure.

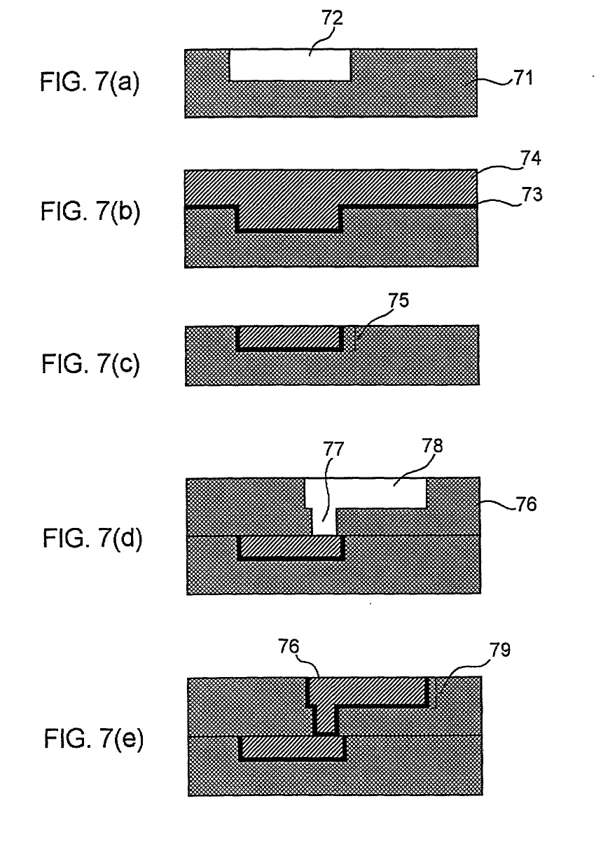

Explanation of symbols:

1: Substrate;

2: SiO₂ film;

3: a-C:F film;

4: SiO₂ film;

5: Resist;

6: Interconnect trench;

7: TiN film;

8: Copper film;

9: Copper interconnect;

10: Cover layer;

11: Fuse section;

12: Bonding pad section;

13: Gold wire bonding.

### DETAILED DESCRIPTION OF THE PREFERRED EMBODIMENT

In the present invention, a film having a protective effect against oxidation is formed under the condition that no oxygen is used and thereafter an anti-reflective coating (ARC) is formed, or alternatively an ARC is formed under the condition that no oxygen is used. In effect, an ARC is formed while the surface of the copper interconnect is protected from oxidation, so as not to peel off, which makes it possible to cope with a further miniaturization of the interconnect pattern.

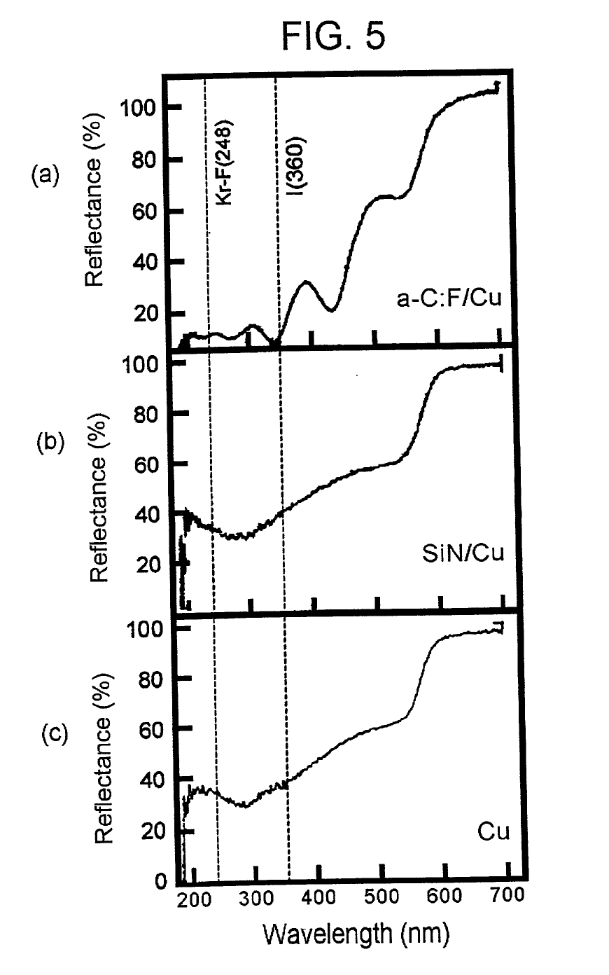

FIG. 5 is a group of graphs showing the wavelength dependences of the reflectance for a copper interconnect, an example in which a SiN film (500 nm in thickness) is formed on the copper interconnect as an etching stopper layer, and an example in which an a-C:F film (500 nm in thickness) that is one embodiment of the present invention is formed on the copper interconnect. As clearly seen in the drawing, a comparison of the reflectances at the wavelengths of the i-line (360 nm) and the Kr-F excimer laser (248 nm) used in photolithography indicates that, while the reflectance of the copper surface and that of the sample in which a SiN film is formed thereon are nearly 40%, the reflectance of the sample with an a-C:F film according to the present invention is 5% or less for the i-line and 10% or less for the Kr-F excimer laser. Although the a-C:F film, in this instance, is formed to a thickness of 500 nm, the reflectance does not depend on the film thickness thereof, and the film has an anti-reflective effect regardless of its film thickness.

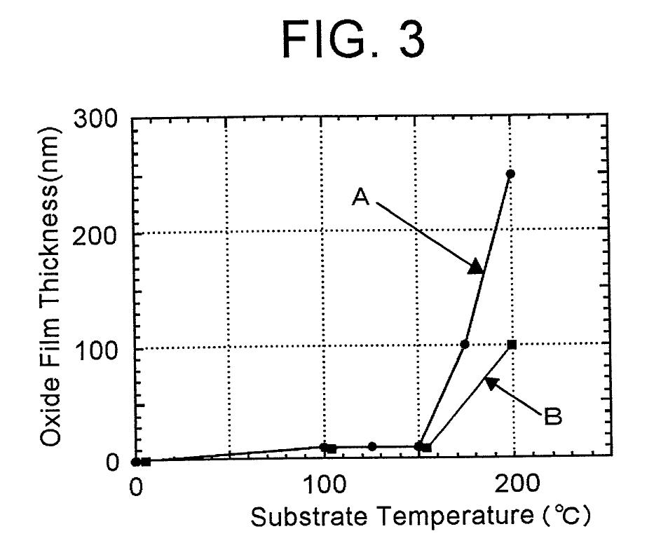

Heated in the air, the copper surface normally starts being oxidized all of a sudden when the substrate temperature exceeds 150° C. (graph A in FIG. 3). As against this, it is evident that the formation of an a-C:F film (100 nm in thickness) on the copper surface suppresses the oxidation (graph B in FIG. 3). It must be noted, however, that the a-C:F film itself allows oxygen to pass through and oxidize the underlying copper, as seen in the graph. Nevertheless, when a SiO₂ film is formed over said a-C:F film, some oxygen may pass therethrough and oxidize the copper surface at the beginning of the SiO₂ film formation, but, once formed, the SiO₂ film cuts off the oxygen penetration and, in consequence, stops further oxidation so that the copper and the a-C:F film remain closely adhered to each other without hindrance.

With respect to the film thickness of the a-C:F film, there is no special limitation. However, because an excessively thin film has a tendency to let oxygen pass through and oxidize the underlying copper, the film is preferably formed to a thickness of at least 50 nm, and more preferably 100 nm or more. The maximum can be set appropriately, according to the design.

Further, in the case that a SiN film is formed as a protective layer against oxygen penetration and, over that, a SiON film or a SiC film is formed, it is sufficient for the SiN film to be formed to a thickness similar to the one when formed as an ordinary etching stopper layer, that is, 50 nm at least and more preferably 100 nm or so. Also, for the SiON film or the SiC film formed on the SiN film, the required film thickness is the same, 50 nm at least and more preferably 100 nm or so. Further, in the case of the SiC film, because oxygen is not used during the film formation, this film can be formed directly over the copper interconnect so as to serve as an ARC as well.

First Embodiment

First, referring to the drawings, a method of forming a multilevel copper interconnect that is one embodiment of the present invention is described.

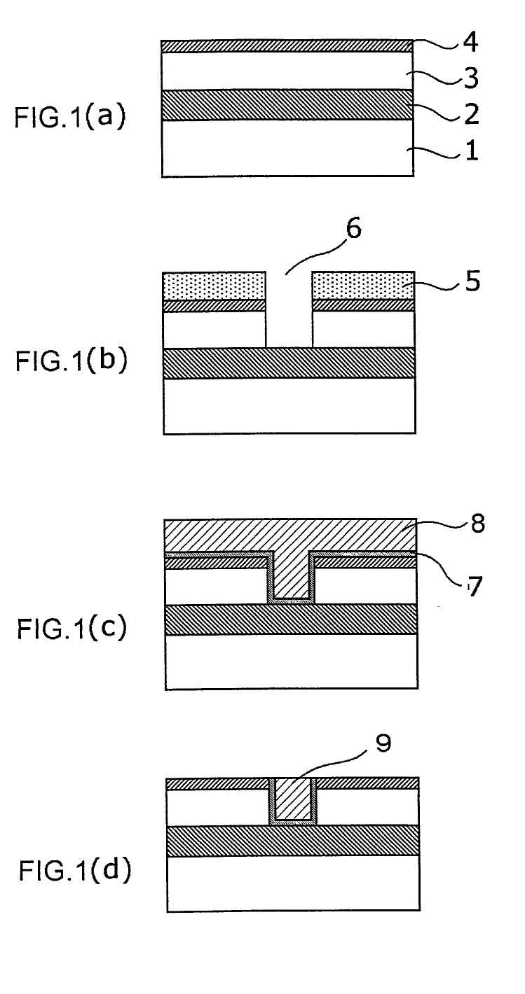

After a SiO₂ film 2 is formed over the surface of a substrate 1, an a-C:F film 3 is formed to a thickness of 500 nm or so. Over that, a SiO₂ film 4 is further formed to a thickness of 200 nm or so by the CVD method (FIG. 1(a)). Over the SiO₂ film 4 formed in this manner, a resist 5 is applied and then patterned by means of lithography. A trench (0.15 μm in width and 0.2 min depth) to forma copper interconnect by a damascene technique is, subsequently, formed in the a-C:F film 3 and the SiO₂film 4 by etching (FIG. 1(b)). Over the entire surface of the substrate within which the trench 6 is formed, a TiN film 7 as a barrier is formed to a thickness of 150 nm by the sputtering method or the like, and a copper film 8 is formed thereon by the CVD method or the like (FIG. 1(c)). The copper film 8 as well as the TiN film 7 are then polished by the CMP method till the SiO₂ film 2 is exposed, and thereby a copper interconnect 9 is accomplished (FIG. 1(d)).

Further, over the copper interconnect 9 formed in this manner, another trench and/or another via hole to form another copper interconnect by a damascene technique is formed within an a-C:F film 3 and a SiO₂ film 4 by etching in the same manner as described above, and a barrier film as well as a copper film are similarly formed and then the surface is planarized. Repeating these steps, a multilevel interconnect can be accomplished.

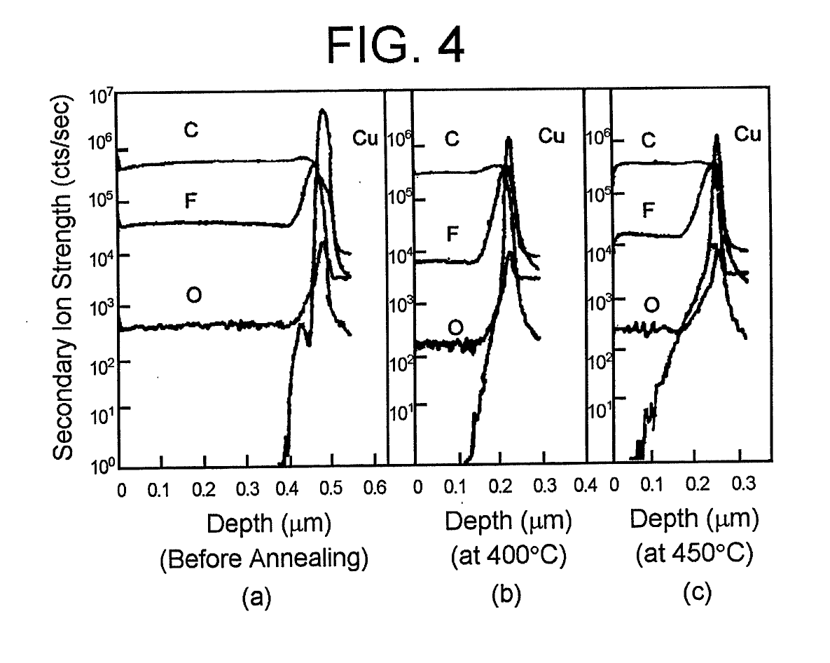

FIG. 4 shows the results of the surface analyses by the SIMS conducted for the samples in which an a-C:F film was formed and thereafter a SiO₂ film was formed at an annealing temperature of 400° C. and 450° C., respectively. On this occasion, the SiO₂ films of respective samples are removed before the measurement. As seen in the drawings, it was confirmed that the copper surface was hardly oxidized after the annealing at either temperature, in comparison with that before the annealing.

In the present example, since the a-C:F film 3 has such an exceptionally strong anti-reflective effect as shown in the afore-mentioned FIG. 5, the resist does not collapse at the time of lithography and a minute pattern can be formed successfully.

Meanwhile, after the multilevel interconnect is accomplished as described above, etching is fittingly applied to a cover layer 10 (may have the same composition as said interlayer insulating film) that is the top-level layer thereof, and thereby a bonding pad section 12 as well as a fuse section 11 are formed. At this, as shown in Fig, 2, by forming at least the fuse section 11 and preferably both sections from an appropriate interconnect material other than copper, aluminium in this instance, the following advantages can be obtained. That is, when an excess current that may give adverse effects on elements is applied, said fuse section is blown and the circuit is protected. Further, if the bonding pad section is also formed from a material other than copper, the inexpensive gold wire bonding 13 can be employed. If the cost permits, the bonding pad section may be formed from copper and, in that case, as the conventional example, a lead bump may be formed to make a flip chip bonding. Needless to say, it is possible to make a flip chip bonding with a bonding pad section formed from a metal other than copper. Further, although, in the drawing, the copper interconnect 9 illustrated has a four-level structure, it is to be understood that this does not limit the present invention.

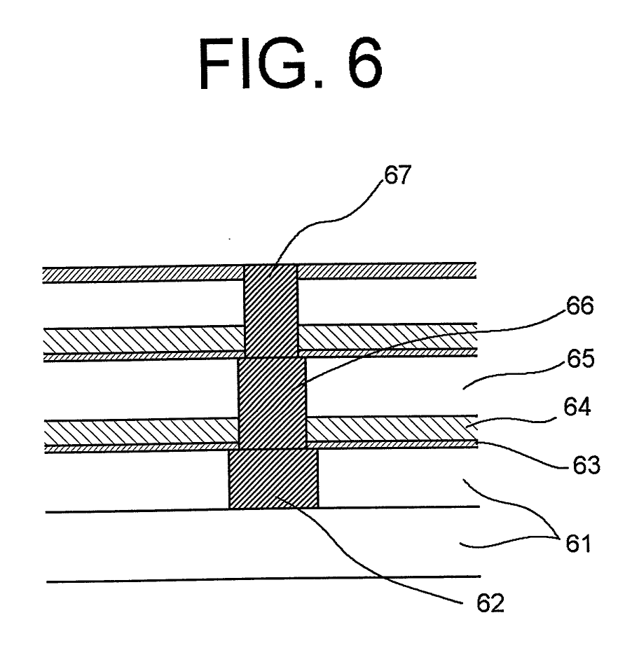

Second Embodiment Referring to FIG. 6, Second embodiment of the present invention is described. FIG. 6 is a schematic cross-sectional view showing a copper multilevel interconnect of the present example.

In an insulating film such as a SiO₂ film 61 that is formed over a substrate, a trench to form a copper interconnect by a damascene technique is formed and then a barrier film and a copper film are formed as First Embodiment. The surface is planarized similarly by the CMP method and thereby a first-level interconnect 62 is accomplished. Next, over the first-level interconnect 62, a SiN film 63 is grown to a thickness of 150 nm by the CVD method, using a silane gas and an ammonia gas, and, over that, a SiON film 64 is further grown to a thickness of 150 nm, using a silane gas and nitrogen oxide. Then, after an insulating film such as a SiO₂ film 65 or the like is formed, another trench and/or another via hole to form a second-level interconnect 66 by a damascene technique is formed by means of lithography. A prescribed trench is, hereon, successfully formed without receiving the reflection from the underlying interconnect or making a resist collapsed. After that, formation of a barrier film and damascene of copper are performed in the same manner as described above and thereby a second-level interconnect 66 is formed. Repeating these steps further in the same manner, a multilevel interconnect in the form of damascene can be accomplished. Further, although the interconnects are illustrated only up to the third level in FIG. 6, it is to be understood that the interconnect structure can have any prescribed number of levels. Further, as described above, by forming at least a fuse section of the top-level layer from an appropriate material other than copper, a semiconductor device having excellent characteristics can be accomplished as described above.

Further, when a SiC film is used instead of the SiN film, it is confirmed that similar effects can be achieved. Further, it is demonstrated that, even without a SiON film being formed, the SiC film by itself can attain a sufficient anti-reflective effect.

What is claimed is:

1. A semiconductor device whose copper interconnect is formed multilevel in structure; wherein at least one interlayer film lying between layers of the copper interconnect has a layered structure in which an amorphous carbon film containing fluorine and a SiO₂ film are laid in this order from the side of the underlying copper interconnect.

2. The semiconductor device according to claim 1, wherein said layered structure made of an amorphous carbon film containing fluorine and a SiO₂ film is laid over an oxide film formed on a semiconductor substrate, and a copper interconnect is formed within said layered structure by a damascene technique, and thereby a first-level interconnect is accomplished.

3. A semiconductor device whose copper interconnect is formed multilevel in structure; wherein at least one interlayer film lying between layers of the copper interconnect has a layered structure in which a silicon nitride and a silicon nitride oxide are laid in this order from the side of the underlying copper interconnect.

4. A semiconductor device whose copper interconnect is formed multilevel in structure; wherein at least one interlayer film lying between layers of the copper interconnect has a layered structure in which a silicon nitride and a silicon carbide are laid in this order from the side of the underlying copper interconnect.

5. A semiconductor device whose copper interconnect is formed multilevel in structure; wherein at least one interlayer film lying between layers of the copper interconnect comprises a silicon carbide layer on the side of the underlying copper interconnect.

6. A method of manufacturing a semiconductor device having a multilevel copper interconnect; which comprises the steps of:
forming an insulating layer over a copper interconnect; and, in forming, within said insulating layer, a trench to form another copper interconnect by a damascene technique and/or a via hole to bring out a contact with a lower-level copper interconnect:
forming, at least on the underlying copper interconnect, a layered structure made of an amorphous carbon film containing fluorine and a SiO₂ film; and
forming said trench and/or said via hole by patterning said layered structure by means of lithography and thereby accomplishing an upper-level copper interconnect in the form of damascene.

7. The method of manufacturing a semiconductor device according to claim 6, which further comprises the steps of:
forming a layered structure made of an amorphous carbon film containing fluorine and a SiO₂ film over an oxide film formed on a semiconductor substrate; and
forming a copper interconnect within said layered structure in the form of damascene, and thereby accomplishing a first-level interconnect.

8. A method of manufacturing a semiconductor device having a multilevel copper interconnect; which comprises the steps of:
forming an insulating layer over a copper interconnect; and, in forming, within said insulating layer, a trench to form another copper interconnect by a damascene technique and/or a via hole to bring out a contact with a lower-level copper interconnect:
forming, at least on the underlying copper interconnect, a layered structure in which a silicon nitride and a silicon nitride oxide are laid in this order from the side of the underlying copper interconnect; and
forming an interlayer insulating film thereon and thereafter forming said trench and/or said via hole by patterning said interlayer insulating film as well as said layered structure by means of lithography and thereby accomplishing an upper-level copper interconnect in the form of damascene.

9. A method of manufacturing a semiconductor device having a multilevel copper interconnect; which comprises the steps of:
forming an insulating layer over a copper interconnect; and, in forming, within said insulating layer, a trench to form another copper interconnect by a damascene technique and/or a via hole to bring out a contact with a lower-level copper interconnect:
forming, at least on the underlying copper interconnect, a layered structure in which a silicon nitride and a silicon carbide are laid in this order from the side of the underlying copper interconnect; and
forming an interlayer insulating film thereon and thereafter forming said trench and/or said via hole by patterning said interlayer insulating film as well as said layered structure by means of lithography and thereby accomplishing an upper-level copper interconnect in the form of damascene.

10. A method of manufacturing a semiconductor device having a multilevel copper interconnect; which comprises the steps of:
forming an insulating layer over a copper interconnect; and, in forming, within said insulating layer, a trench to form another copper interconnect by a damascene technique and/or a via hole to bring out a contact with a lower-level copper interconnect:
forming, at least on the underlying copper interconnect, a silicon carbide on the side of the underlying copper interconnect; and
forming an interlayer insulating film thereon and thereafter forming said trench and/or said via hole by patterning said interlayer insulating film as well as said silicon carbide by means of lithography and thereby accomplishing an upper-level copper interconnect in the form of damascene.
